(19) United States
(12) Patent Application Publication
(10) Pub. No.: US 2025/0054856 A1
(43) Pub. Date: Feb. 13, 2025

(54) SEMICONDUCTOR DEVICE WITHIN INTERCONNECT STRUCTURE

(71) Applicant: Intel Corporation, Santa Clara, CA (US)

(72) Inventor: Yao-Feng Chang, Bellemont, AZ (US)

(73) Assignee: Intel Corporation, Santa Clara, CA (US)

(21) Appl. No.: 18/447,461

(22) Filed: Aug. 10, 2023

(51) Int. Cl. H01L 23/522; H01L 23/525

(52) U.S. Cl. CPC H01L 23/5226; H01L 23/5252

(57) ABSTRACT

Techniques for forming a semiconductor device (such as a metal-semiconductor-metal device) within the interconnect region over a device layer (such as plurality of field effect transistor (FET) devices). An interconnect layer within a stack of interconnect layers includes a metal-semiconductor-metal (MSM) structure having a first metal layer, a semiconductor layer on the first metal layer, and a second metal layer on the semiconductor layer. The first metal layer may be directly on a first conductive layer of a lower interconnect layer (such as on a via or line of the lower interconnect layer). One or more other conductive layers may also be disposed between the first metal layer and the underlying first conductive layer. A second conductive layer may contact the top surface of the second metal layer.

### FIELD OF THE DISCLOSURE

The present disclosure relates to integrated circuits, and more particularly, to semiconductor devices integrated within interconnect structures.

### BACKGROUND

As integrated circuits continue to scale downward in size, a number of challenges arise. For various applications, it is desirable for certain transistor structures to have thicker dielectric gates compared to other transistor structures. However, the fabrication of these thick gate structures is challenging to integrate with thinner gate structures. For example, there remain a number of non-trivial challenges with respect to incorporating field effect transistor (FET) devices having thicker gates than other FET devices on the same chip.

### BRIEF DESCRIPTION OF THE DRAWINGS

FIG. 1 is a cross-sectional view that illustrates an example portion of an integrated circuit configured with an interconnect region over a plurality of semiconductor devices, in accordance with an embodiment of the present disclosure.

FIG. 2A is a cross-sectional view that illustrates a portion of the interconnect region having a semiconductor device integrated therewithin, in accordance with an embodiment of the present disclosure.

FIG. 2B is a cross-sectional view that illustrates a portion of an interconnect region having more than one semiconductor device integrated therewithin, in accordance with another embodiment of the present disclosure.

FIGS. 3A-3G are cross-sectional views that collectively illustrate an example process for forming an interconnect region having a semiconductor device integrated therewithin, in accordance with some embodiments of the present disclosure.

FIG. 4 illustrates a schematic of an anti-fuse circuit, in accordance with an embodiment of the present disclosure.

FIG. 5 illustrates a cross-section view of a chip package containing one or more semiconductor dies, in accordance with an embodiment of the present disclosure.

FIG. 6 is a flowchart of a fabrication process for an integrated circuit including an interconnect region having a semiconductor device integrated within the interconnect region, in accordance with an embodiment of the present disclosure.

FIG. 7 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein for forming a semiconductor device within the interconnect region over a plurality of field effect transistor (FET) devices. Although the techniques can be used in any number of integrated circuit applications, they are particularly useful with respect to forming metal-semiconductor-metal (MSM) devices and contacting schemes for size-constrained transistors such as those used in logic and memory cells. Example such cells may include, for instance, memory cells that include an anti-fuse configuration having a memory element and an access device. In some such examples, the access devices of such cells are implemented within an interconnect structure. The access devices can be implemented as MSM devices. According to some such embodiments, an interconnect layer within a stack of interconnect layers includes an MSM structure having a first metal layer, a semiconductor layer on the first metal layer, and a second metal layer on the semiconductor layer. The first metal layer may be, for example, directly on a first conductive layer of a lower interconnect layer (such as on a via or line of the lower interconnect layer). One or more other conductive layers may also be disposed between the first metal layer and the underlying first conductive layer. A second conductive layer of that same interconnect layer, or an upper interconnect layer, may contact the top surface of the second metal layer. The MSM structures may be used, for example, to replace FET devices with larger dielectric gates and can be integrated within a chip having a plurality of other FET devices.

### General Overview

As previously noted above, it can be challenging to integrate FET devices with thick gate dielectrics with other FET devices having thinner gate dielectrics. Such thick-gate FET devices may be used within backend of line (BEOL) anti-fuse circuits where a fuse element or memory element is arranged in series with an access device. These anti-fuse circuits may be used in several applications, such as one-time programmable or reconfigurable read-only-memory (ROM), root-of-trust implementations for memory redundancy, and for on-chip security keys. Anti-fuse circuits use a relatively large voltage (e.g., around 5 V) during a programming operation to cause dielectric breakdown of the gate of the fuse element, thus shorting across the fuse element. Accordingly, the access device coupled with the anti-fuse element requires a FET with a thick gate dielectric to handle the relatively high current associated with the programming operation. But the incorporation of thick-gate FET devices with thinner gate FET devices requires fabrication operations that are relatively high in cost and time consuming, particularly in the context of BEOL processing.

Thus, techniques are provided herein for forming semiconductor devices integrated within an interconnect structure. Although the techniques can be used in any number of applications, they can be used in the context of embedded memory applications, such as a memory array having certain elements formed during BEOL processing. In some such cases, the techniques can be used to replace thick-gate FET devices with MSM structures integrated into the interconnect region above other FET devices of a given device layer. The MSM structure includes a stack of layers that include a first metal layer, a semiconductor layer on the first metal layer, and a second metal layer on the semiconductor layer. According to some embodiments, the entire MSM structure is incorporated within the thickness of one interconnect layer within a stack of interconnect layers. In some examples, the MSM structure functions as a Schottky diode with a Schottky barrier height dependent on the materials used for the metal and semiconductor layers. In some embodiments, the semiconductor layer includes amorphous silicon while the first and second metal layers include titanium or nickel. The integration of the MSM structures within the interconnect region offers both footprint reduction (due to vertical stacking of active devices) and an improvement to device reliability by replacing thick-gate FET devices.

According to an embodiment, an integrated circuit includes a plurality of semiconductor devices, an interconnect region above the plurality of semiconductor devices having a plurality of stacked interconnect layers, a first interconnect layer of the plurality of stacked interconnect layers having a first dielectric layer and a conductive layer, and a second interconnect layer of the plurality of stacked interconnect layers and on the first interconnect layer. The second interconnect layer includes a second dielectric layer over the first dielectric layer, a first metal layer over the conductive layer, a semiconductor layer on the first metal layer, and a second metal layer on the semiconductor layer.

According to another embodiment, an integrated circuit includes a device layer having a plurality of transistors, an interconnect region above the device layer with the interconnect region having a plurality of stacked interconnect layers. An interconnect layer of the plurality of stacked interconnect layers includes a dielectric layer and a via passing through the dielectric layer. The via includes a first metal layer, a semiconductor layer on the first metal layer, a second metal layer on the semiconductor layer, and a conductive layer on the second metal layer.

According to another embodiment, a method of forming an integrated circuit includes forming a first interconnect layer above a plurality of semiconductor devices and forming a second interconnect layer over the first interconnect layer. Forming the first interconnect layer includes forming a first dielectric layer, forming a trench through the first dielectric layer, and forming a first conductive layer in the trench. Forming the second interconnect layer includes forming a first metal layer over the conductive layer, forming a semiconductor layer on the first metal layer, forming a second metal layer on the semiconductor layer, patterning each of the first metal layer, semiconductor layer, and second metal layer to form a metal-semiconductor-metal (MSM) structure over the conductive layer, forming a second dielectric layer over the first dielectric layer and over the MSM structure, forming a via opening in the second dielectric layer over the MSM structure, and forming a second conductive layer in the via opening and contacting the second metal layer of the MSM structure.

The techniques can be used with any type of planar and non-planar transistors, including finFETs (sometimes called double-gate transistors, or tri-gate transistors), nanowire and nanoribbon transistors (sometimes called gate-all-around transistors), and thin film transistors, to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a remove metal gate, or RMG, process). Any number of semiconductor materials can be used in forming the transistors to which power is being supplied by a buried or backside power rail, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate conductive vias or contacts within the interconnect region that include an MSM structure. Such tools may detect the presence of a patterned amorphous silicon layer within one of the interconnect layers. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer.

### Architecture

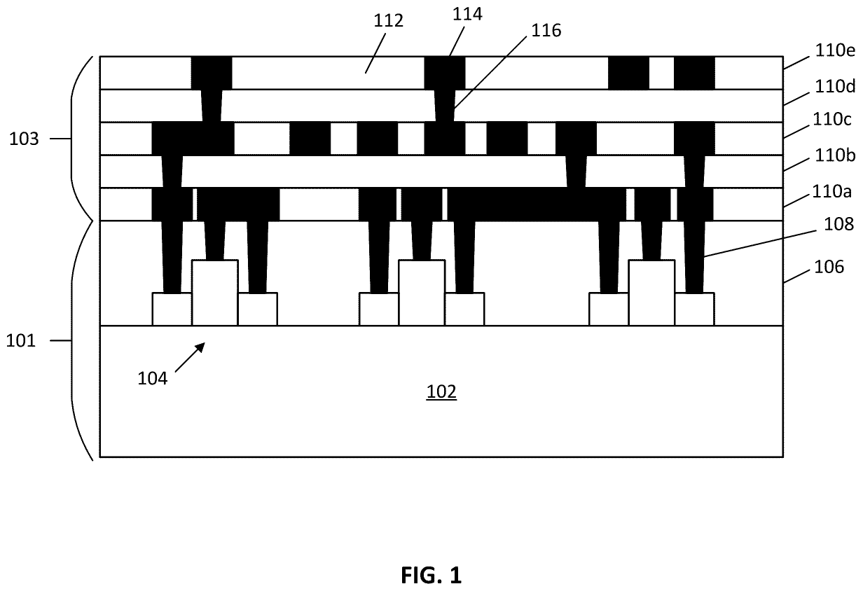

FIG. 1 is a cross-sectional view that illustrates an example portion of an integrated circuit having an interconnect region above a plurality of semiconductor devices, in accordance with an embodiment of the present disclosure. The semiconductor devices in this example are non-planar metal oxide semiconductor (MOS) transistors, such as tri-gate or gate-all-around (GAA) transistors, although other transistor topologies and types can also benefit from the techniques provided herein, as will be appreciated (e.g., planar transistors, thin film transistors, or any other transistors to which contact can be made).

According to some embodiments, the integrated circuit includes a device region 101, and an interconnect region 103 over the device region 101. Device region 101 may include a plurality of semiconductor devices 104 along with one or more other layers or structures associated with the semiconductor devices 104. For example, device region 101 can also include a substrate 102 and one or more dielectric layers 106 that surround active portions or contacts of the semiconductor devices 104. Device region 101 may also include one or more conductive contacts 108 that provide electrical contact to transistor elements such as gate structures, drain regions, or source regions. Conductive contacts 108 include, for example, tungsten, although other metal or metal alloy materials may be used as well. Conductive contacts may also be a part of, or otherwise include, what is sometimes called a local interconnect, which is considered part of the device layer and usually formed prior to any backend processing.

Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, the substrate can be a semiconductor-on-insulator substrate having a desired semiconductor layer over a buried insulator layer (e.g., silicon over silicon dioxide). Alternatively, the substrate can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, backside processing is used to remove substrate 102 and form any number of backside interconnect layers.

Interconnect region 103 includes a plurality of interconnect layers 110a-110e stacked over one another. Each interconnect layer can include a dielectric material 112 along with one or more different conductive features. Dielectric material 112 can be any dielectric, such as silicon oxide, silicon oxycarbide, silicon nitride, or silicon oxynitride. Dielectric material 112 may be deposited using any known dielectric deposition technique such as chemical vapor deposition (CVD), plasma-enhanced chemical vapor deposition (PECVD), flowable CVD, spin-on dielectric, or atomic layer deposition (ALD). The one or more conductive features can include conductive traces 114 and conductive vias 116 arranged in any pattern across the interconnect layers 110a-110e to carry signal and/or power voltages to/from the various semiconductor devices 104. A conducive via, such as conductive via 116, may extend through an interconnect layer to connect between conductive traces on an upper interconnect layer and a lower interconnect layer. In other cases, a via 116 may only extend part way through a given interconnect layer. Although interconnect region 103 is illustrated with only five interconnect layers, any number of interconnect layers can be used within interconnect region 103. Also, this example shows vias and lines in different interconnect layers, in both single and dual damascene configurations. In other examples, vias and lines may also exist within the same interconnect layer, such as in the case of some dual damascene configurations.

Any of conductive traces 114 and conductive vias 116 can include any number of conductive materials, with some examples including copper, ruthenium, tungsten, cobalt, molybdenum, and alloys thereof. In some cases, any of conductive traces 114 and conductive vias 116 include a relatively thin liner or barrier, such as titanium nitride, titanium silicide, tungsten carbo-nitride (WCN), PVD or ALD tungsten, or tantalum nitride. As will be discussed in more detail herein, any of conductive vias 116 may include an MSM structure as part of the conductive via to provide an active semiconductor device (e.g., a diode or access device) within interconnect region 103.

It should be noted that each of the various conductive vias 116 and conductive contacts 108 are shown with tapered profiles to indicate a more natural appearance due to the etching process used to form the openings. Any degree of tapering may be observed depending on the etch parameters used and the thickness of the dielectric layer being etched through. Furthermore, conductive vias may be stacked one over the other through different dielectric layers of interconnect region 103. However, in some examples, a single via recess may be formed through more than one dielectric layer yielding a taller, more tapered conductive via that extends through two or more dielectric layers.

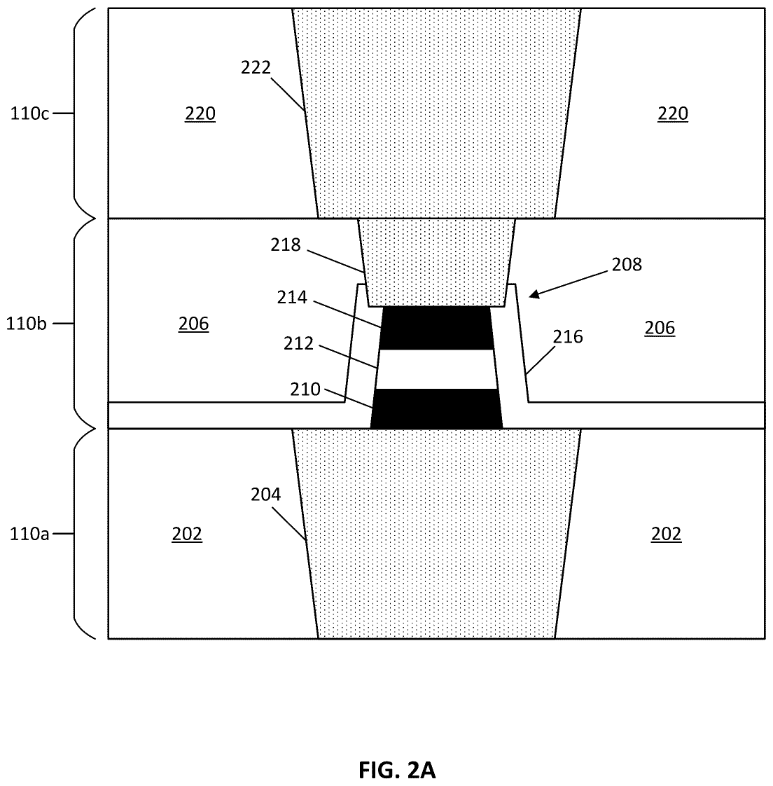

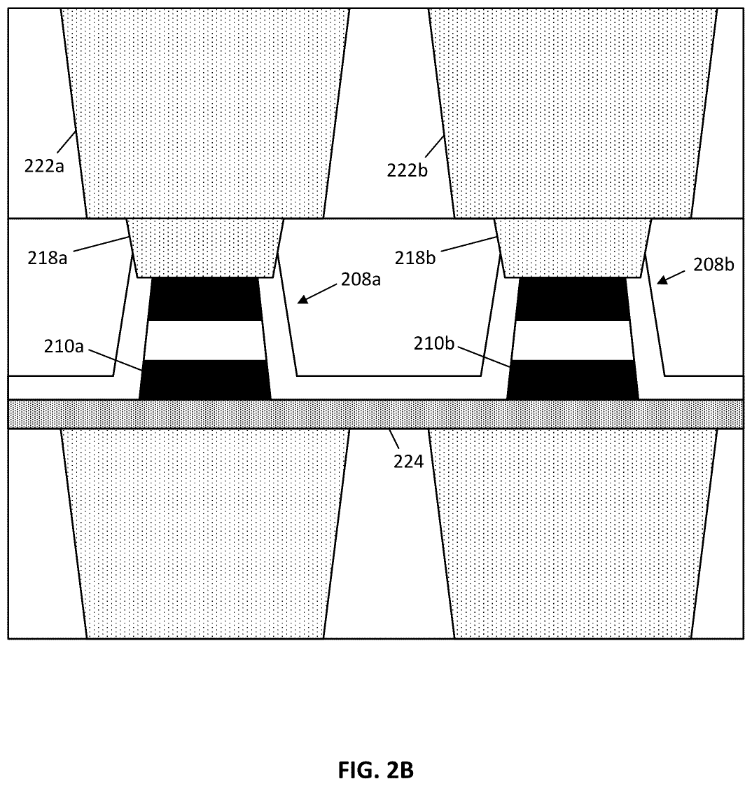

FIG. 2A illustrates a more detailed cross-section view of three interconnect layers of the integrated circuit from FIG. 1, according to an embodiment. The illustrated example includes interconnect layers 110a-110c, although any three sequential interconnect layers could include similar structures discussed herein. In other examples, layer 110a might be part of a local interconnect of a given device layer. In still other examples, layer 110b may be the only interconnect layer. In still other examples, the device of layer 110b may be formed at least in part in two or more interconnect layers. Other features may also be included. For instance, there may be a relatively thin etch stop layer (e.g., silicon nitride having a thickness in the range of 2 nm to 6 nm) between layers 110a and 110b, and between layers 110b and 110c. Any number of configurations will be apparent in light of this disclosure.

A first interconnect layer 110a includes a first dielectric layer 202 and a first conductive layer 204. First dielectric layer 202 may be similar to dielectric material 112, as discussed above, and first conductive layer 204 may be similar to conductive trace 114, as discussed above. In some examples, first dielectric layer 202 may be referred to as an interlayer dielectric (ILD), and first conductive layer 204 may be, for instance, a conductive line or a conductive via of the first interconnect layer 110a. In still other examples, first conductive layer 204 may be a contact or local interconnect feature of an underlying device layer.

According to some embodiments, a second interconnect layer 110b on first interconnect layer 110a includes a second dielectric layer 206 and a via structure 208 that is made up of various layers. Second dielectric layer 206 may be similar to first dielectric layer 202 and may include the same material composition (e.g., silicon dioxide, or other ILD material). As further shown in this example, via structure 208 includes an MSM structure having a first metal layer 210, a semiconductor layer 212, and a second metal layer 214. Via structure 208 may also include a second conductive layer 218 that extends down to contact second metal layer 214. In some other embodiments, there is no second conductive layer 218, such that the MSM structure extends to the top surface of layer 110b. In some embodiments, one or more additional conductive layers may be formed beneath first metal layer 210, such that the one or more additional conductive layers are between first metal layer 210 and first conductive layer 204.

In some examples, first metal layer 210 and second metal layer 214 include titanium or nickel, although other conductive materials may be used. First metal layer 210 and second metal layer 214 may have substantially the same thickness (e.g., between about 7 nm and about 13 nm), but they need not be the same in all cases. Semiconductor layer 212 may include an amorphous semiconductor material, such as amorphous silicon, amorphous silicon germanium, or amorphous germanium, or any of these examples further including hydrogen, such as hydrogenated amorphous silicon (a-Si: H) or hydrogenated amorphous SiGe (a-SiGe: H). In some examples, semiconductor layer 212 may have a thickness between about 10 nm and about 20 nm, and may be intrinsic semiconductor material or include n-type or p-type dopants. The Schottky barrier height for the MSM structure may be determined based on the metal materials used (e.g., titanium or nickel) and on the semiconductor material and doping profile (if any) of the semiconductor material. For example, the Schottky barrier height between titanium and amorphous silicon is about 0.79 eV, and the Schottky barrier height between nickel and amorphous silicon is about 0.86 eV. The bandgap of hydrogenated amorphous silicon is around 1.6-1.8 eV. Titanium is usually pinned at midgap at silicon interface, and nickel is usually pinned closer to the valence band of silicon. The ideality factors are 1.18 and 1.36 for titanium and nickel, respectively.

According to some embodiments, a dielectric liner 216 may cover the sidewalls of the MSM structure. Thus, dielectric liner 216 may be present along sidewalls of each of first metal layer 210, semiconductor layer 212, and second metal layer 214. In some examples, dielectric liner 216 may include silicon nitride and may have a thickness between about 5 nm and about 10 nm. Other examples may use other dielectric liners (e.g., silicon carbide, silicon oxynitride, silicon oxycarbide, silicon oxycarbonitride).

A third interconnect layer 110c includes a third dielectric layer 220 and a third conductive layer 222. Third dielectric layer 220 may be similar to first dielectric layer 202 and second dielectric layer 206 and may include the same material composition as each of first dielectric layer 202 and second dielectric layer 206 (e.g., silicon dioxide, or other ILD material). Third conductive layer 222 may include the same material composition as first conductive layer 204 and/or second conductive layer 218. In some examples, third conductive layer 222 may be, for instance, a conductive line or a conductive via of the third interconnect layer 110c.

According to some embodiments, the MSM structure makes up a portion of via structure 208. For example, in the absence of the MSM structure, second conductive layer 218 may be the only conductive via material extending between third conductive layer 222 and first conductive layer 204. With the presence of the MSM structure, second conductive layer 218 extends between third conductive layer 222 and second metal layer 214. Second conductive layer 218 may also contact each of third conductive layer 222 and second metal layer 214. Although only one MSM structure is shown in FIG. 2A, any number of similar MSM structures may be formed within the same interconnect layer and/or within any number of other interconnect layers. In some examples, the MSM structures are formed as part of via structures within interconnect layers that include only via structures. In some such cases, one or more vias in layer 110b extend fully from the top of layer 110b to the bottom of layer 110b, while one or more other vias in layer 110b are configured with an MSM structure similar to that shown.

Any number of MSM structures within the same interconnect layer may be electrically coupled together. FIG. 2B illustrates an example with two via structures 208a and 208b within the same interconnect layer and each having a corresponding MSM structure. According to some embodiments, a fourth conductive layer 224 may be provided below each of the MSM structures and contacting (or otherwise conductively coupled to) each of first metal layer 210a and second metal layer 210b of the MSM structures. Any number of MSM structures within the same interconnect layer may be coupled together using fourth conductive layer 224. According to some embodiments, fourth conductive layer 224 includes titanium nitride, although other conductive materials (e.g., titanium, tantalum, tantalum nitride, nickel, copper, silver, aluminum, or ruthenium) can be used as well. In some embodiments, fourth conductive layer 224 is provided along the top of the second interconnect layer, rather than the bottom. For example, fourth conductive layer 224 may be formed between second conductive layers 218a/218b and third conductive layers 222a/222b.

### Fabrication Methodology

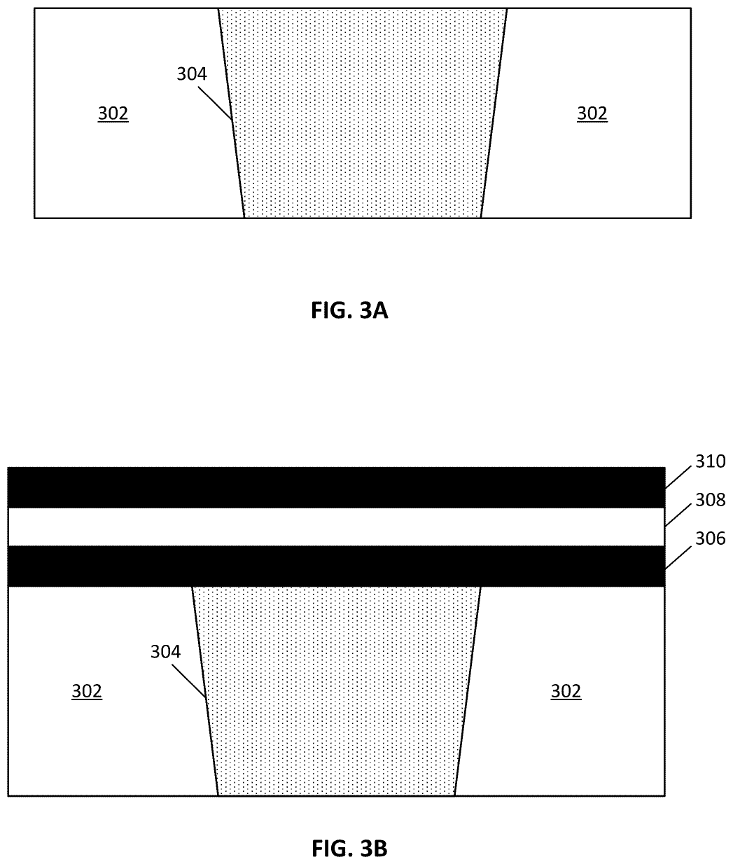

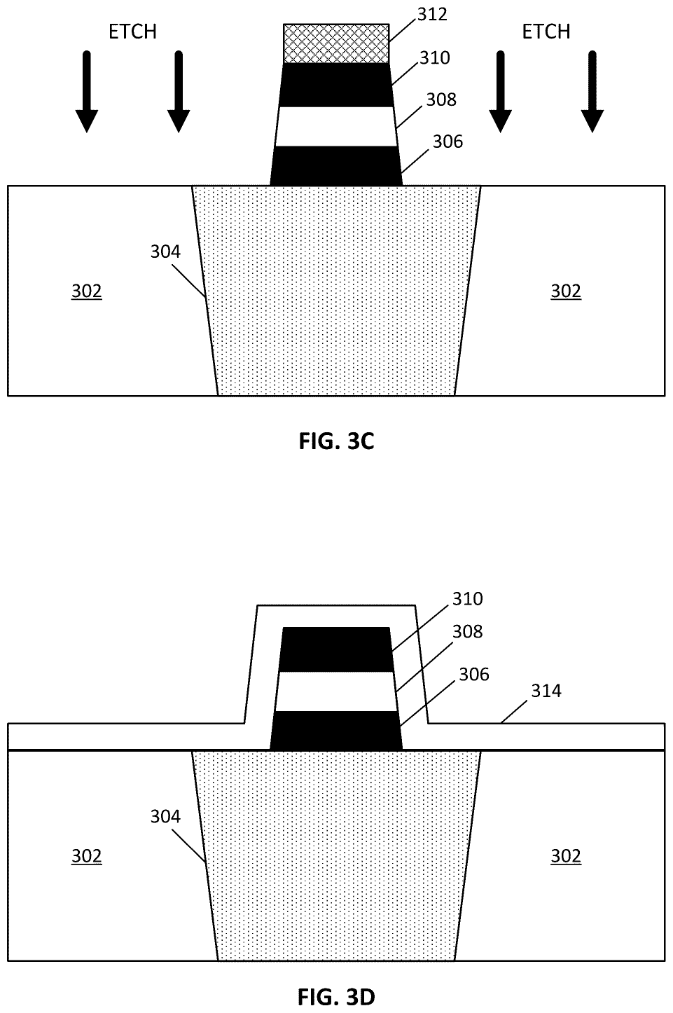

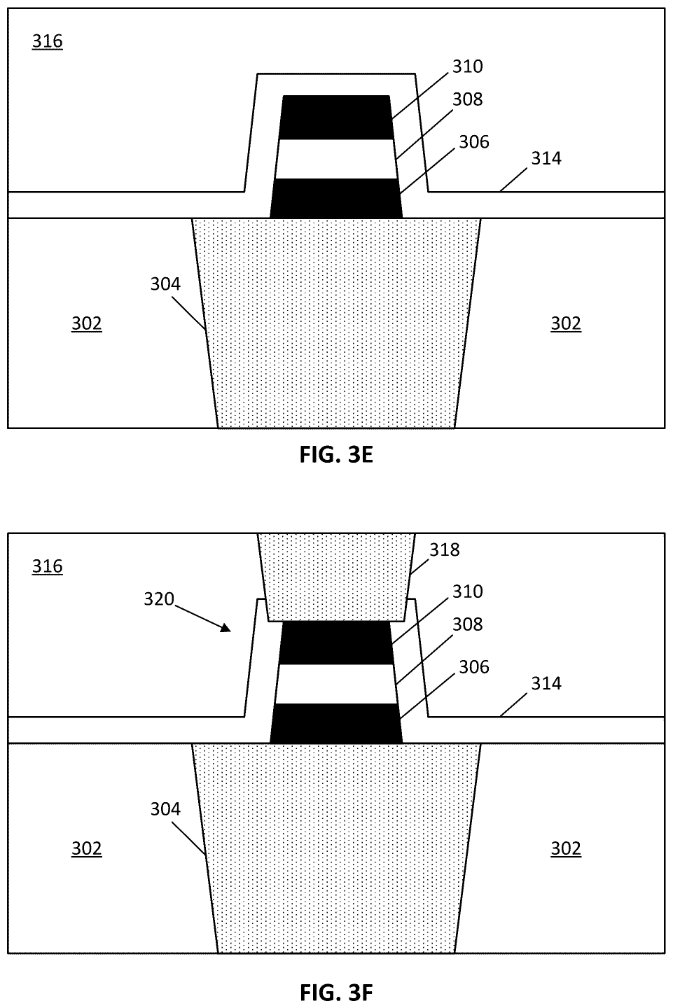

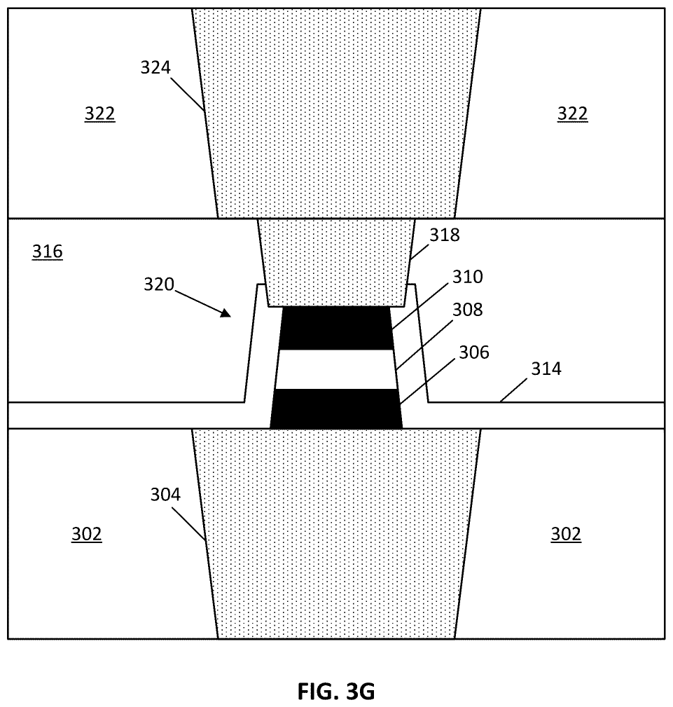

FIGS. 3A-3G are cross-sectional views that collectively illustrate an example process for forming a portion of an interconnect region of an integrated circuit, in accordance with an embodiment of the present disclosure. Each figure shows an example structure that results from the process flow up to that point in time, so the depicted structure evolves as the process flow continues, culminating in the structure shown in FIG. 3G, which is similar to the structure illustrated in FIG. 2A. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 3A is a cross sectional view taken through a first interconnect layer of a plurality of stacked interconnect layers. Accordingly, the illustrated first interconnect layer may be at any position within interconnect region 103. The first interconnect layer includes a first dielectric layer 302 that may be any dielectric material, such as silicon oxide, silicon oxynitride, silicon nitride, or silicon oxycarbide. First dielectric layer 302 may be deposited using any known dielectric deposition technique, such as CVD, PECVD, flowable CVD, spin-on dielectric, or ALD. First dielectric layer 302 may have a height between about 30 nm and about 70 nm.

According to some embodiments, an opening is formed through first dielectric layer 302 and a first conductive layer 304 is formed within the opening. The opening may be formed using any anisotropic etching technique, such as using reactive ion etching (RIE) while masking the unetched regions of first dielectric layer 302 with either a photoresist or hard mask. According to some embodiments, first conductive layer 304 is copper that is deposited using any one of electroplating, electroless plating. CVD, or PECVD, to name a few examples. Any other suitable conductive materials may be used as well (e.g., aluminum, ruthenium). After deposition of first conductive layer 304, a polishing process may be performed using, for example, chemical mechanical polishing (CMP) to planarize a top surface of both first conductive layer 304 and first dielectric layer 302. In some embodiments, a thin barrier layer is deposited along the inner surfaces of the opening prior to the formation of first conductive layer 304. The thin barrier layer may include, for example, titanium or tantalum (e.g., titanium nitride or tantalum nitride, having a thickness in the range of 2 nm to 6 nm). In some examples, an etch stop layer may be provided prior to forming the next layer. The etch stop layer may include, for example, a nitride or carbide or other suitable dielectric material (e.g., silicon nitride having a thickness in the range of 2 nm to 6 nm).

FIG. 3B is a cross sectional view of the structure depicted in FIG. 3A, after formation of various material layers over the first interconnect layer. In some embodiments, a first metal layer 306 is formed over the first interconnect layer, a semiconductor layer 308 is formed on first metal layer 306, and a second metal layer 310 is formed on semiconductor layer 310. First metal layer 306 may be formed directly on first conductive layer 304. In some other examples, any number of other conductive layers are present between first metal layer 306 and first conductive layer 304. If a non-conductive layer is present over first conductive layer 304 (such as an etch stop layer), then lithography can be used to create an opening in the non-conductive layer over first conductive layer 304, so that first metal layer 306 can conductively contact the underlying first conductive layer 304 or some intervening conductive layer, as the case may be. Each of first metal layer 306, semiconductor layer 308, and second metal layer 310 may be deposited using any suitable deposition technique, such as CVD, ALD, PECVD, or physical vapor deposition (PVD).

In some examples, first metal layer 306 and second metal layer 310 may each include titanium or nickel to provide bottom and top electrodes of a Schottky diode, respectively. Semiconductor layer 308 may include, for example, undoped silicon, undoped germanium, undoped silicon germanium, undoped amorphous silicon, undoped amorphous germanium, undoped amorphous silicon germanium, or a hydrogenated version of any of these. In some other embodiments, semiconductor layer 308 includes n or p type dopants. In some examples, both first metal layer 306 and second metal layer 310 may have a thickness of around 10 nm, and semiconductor layer 308 may have a thickness between about 10 nm and about 20 nm, such as around 15 nm.

FIG. 3C is a cross sectional view of the structure depicted in FIG. 3B, after formation of masking layer 312 and an etching process to form an MSM structure from first metal layer 306, semiconductor layer 308, and second metal layer 310. Masking layer 312 may be any suitable photoresist or hard mask material (e.g., nitride or carbide). An anisotropic etching process may be used to etch away portions of first metal layer 306, semiconductor layer 308, and second metal layer 310 that are not protected by masking layer 312. Note that the resulting MSM structure may have sidewalls that taper outward slightly due to effects from the etching process. The etch may be controlled to stop once first dielectric layer 302 has been exposed, however, some portion of first dielectric layer 302 and/or first conductive layer 304 may be removed as well by the etching process (e.g., if not covered by an etch stop).

FIG. 3D is a cross sectional view of the structure depicted in FIG. 3C, after formation of a dielectric liner 314 over the MSM structure, according to some embodiments. Dielectric liner 314 may be deposited using any suitable conformal deposition technique, such as CVD or ALD, and includes a dielectric material. In some examples, dielectric liner 314 includes silicon nitride and has a thickness between about 5 nm and about 10 nm.

FIG. 3E is a cross sectional view of the structure depicted in FIG. 3D, after formation of a second dielectric layer 316 over the MSM structure. Second dielectric layer 316 may be any dielectric material, such as silicon oxide, silicon oxynitride, silicon nitride, or silicon oxycarbide. Second dielectric layer 316 may be deposited using any known dielectric deposition technique, such as CVD, PECVD, flowable CVD, spin-on dielectric, or ALD. In some examples, second dielectric layer 316 may have a height between about 30 nm and about 70 nm, although such height can vary from one embodiment to the next. According to some embodiments, second dielectric layer 316 represents the dielectric layer of a second interconnect layer above the first interconnect layer. A top surface of second dielectric layer may be polished using, for example, CMP to planarize its top surface (e.g., to remove any bump or other topology caused by the presence of the MSM structure.

FIG. 3F is a cross sectional view of the structure depicted in FIG. 3E, after the formation of a second conductive layer 318 through a portion of second dielectric layer 316, according to some embodiments. An opening is formed through a portion of second dielectric layer 316 and through a portion of dielectric liner 314 to expose at least a portion of second metal layer 310. The opening may be formed using any anisotropic etching technique, such as using RIE while masking the unetched regions of second dielectric layer 316 with either a photoresist or hard mask. The RIE etching process may etch through both second dielectric layer 316 and dielectric liner 314, and any other intervening layer that may be present (e.g., etch stop layer).

Second conductive layer 318 may include copper, aluminum, ruthenium, or other conductive material that is deposited using any one of electroplating, electroless plating, CVD, or PECVD, to name a few examples. Any other suitable conductive materials may be used as well. After deposition of second conductive layer 318, a polishing process may be performed using, for example, CMP to planarize a top surface of both second conductive layer 318 and second dielectric layer 316. In some embodiments, a thin barrier layer is deposited along the inner surfaces of the opening prior to the formation of second conductive layer 318. The thin barrier layer may include, for instance, titanium or tantalum and may be considered an integral part of second conductive layer 318 (e.g., a structure having a tantalum nitride barrier layer on a copper core 318). According to some embodiments, the stack of at least second conductive layer 318, second metal layer 310, semiconductor layer 308, and first metal layer 306 provide a via structure 320 that is conductively coupled with the underlying first conductive layer 304.

FIG. 3G is a cross sectional view of the structure depicted in FIG. 3F, after formation of a third interconnect layer on the second interconnect layer, according to an embodiment of the present disclosure. The third interconnect layer includes a third dielectric layer 322 that may be any dielectric material, such as silicon oxide, silicon oxynitride, silicon nitride, or silicon oxycarbide. Third dielectric layer 322 may be deposited using any known dielectric deposition technique, such as CVD, PECVD, flowable CVD, spin-on dielectric, or ALD. Third dielectric layer 322 may have a height, for example, between about 30 nm and about 70 nm.

According to some embodiments, an opening is formed through third dielectric layer 322 and over at least a portion of second conductive layer 318, such that at least a portion of second conductive layer 318 is exposed by the opening through third dielectric layer 322. A third conductive layer 324 is formed within the opening. The opening may be formed using any anisotropic etching technique, such as using RIE while masking the unetched regions of third dielectric layer 322 with either a photoresist or hard mask. According to some embodiments, third conductive layer 324 is copper that is deposited using any one of electroplating, electroless plating, CVD, or PECVD, to name a few examples. Any other suitable conductive materials may be used as well. After deposition of third conductive layer 324, a polishing process may be performed using, for example, CMP to planarize a top surface of both third conductive layer 324 and third dielectric layer 322. In some embodiments, a thin barrier layer is deposited along the inner surfaces of the opening prior to the formation of third conductive layer 324. The thin barrier layer may include, for instance, titanium or tantalum. According to some embodiments, via structure 320 extends between first conductive layer 304 and third conductive layer 324. In some embodiments, via structure 320 directly contacts both first conductive layer 304 and third conductive layer 324.

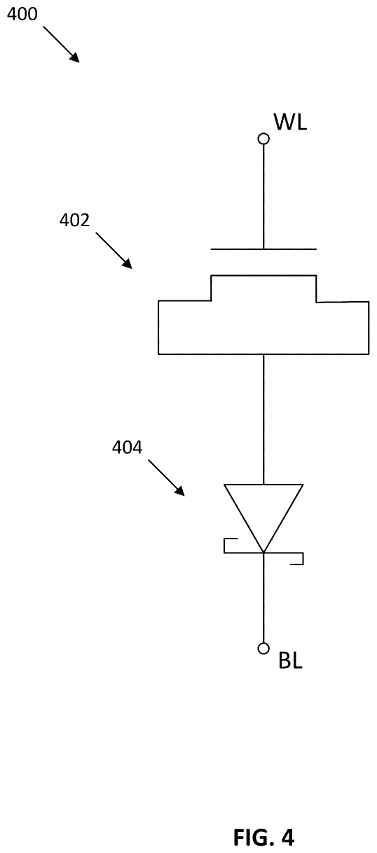

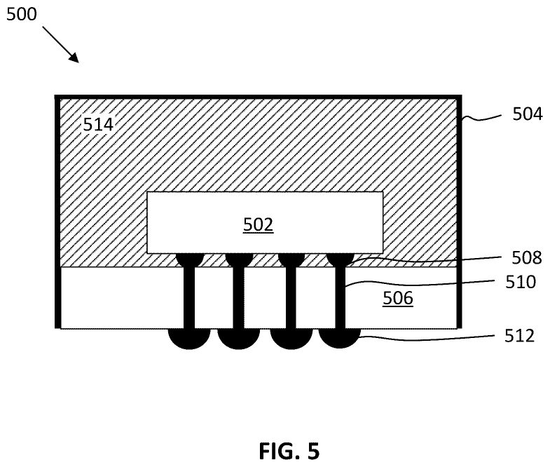

FIG. 4 illustrates an example schematic of an anti-fuse circuit 400, according to some embodiments. Anti-fuse circuit 400 includes a memory element 402 in series with an access device 404. Memory element 402 may include any number of FET devices with their source and drain terminals shorted together, such that the only conductive path that exists through memory element 402 is through the gate dielectric following dielectric breakdown.

According to some embodiments, access device 404 includes a Schottky diode, which may be implemented using the MSM structure described herein, such as shown at 208 in FIG. 2A, at 208a or 208b in FIG. 2B, or at 320 in FIG. 3G. In some such cases, memory element 402 may be formed on top of (or below) the MSM structure, either in the same interconnect layer or in the upper or lower interconnect layer, so as to provide a memory cell within the interconnect structure. Any number of such memory cells can be formed within the overall interconnect structure. When a high enough potential is applied across memory element 402, by way of the word line (WL) and bit line (BL), such as around 5 V, dielectric breakdown of memory element 402 occurs and effectively shorts memory element 402. This can be done during a programming operation. Any number of anti-fuse circuits can be densely arrayed to provide permanent ‘0’ or ‘1’ bits depending on the state of memory element 402. For instance, memory element 402 provides a ‘0’ in its non-shorted state, and a ‘1’ in its shorted state. In any case, the stored value can subsequently be read out, during a read operation.

In more detail, prior to being programmed, the memory element 402 has capacitor-like qualities (two conductive plates sandwiching a dielectric material). A program voltage (e.g., 5 V) can be applied via the WL corresponding to that bitcell, and lower voltage can be applied to the BL (e.g., ground). During such a programming operation, the access device 404 of that bitcell is forward biased so as to allow current to flow on the corresponding WL and through the memory element 402 of that bitcell to the corresponding BL. The access device 404 of other bitcells in the same row as the bitcell being programmed are reverse-biased by an appropriate voltage provided on their corresponding BLs. Likewise, the access device 404 of other bitcells in the same column as the bitcell being programmed are reverse-biased by an appropriate voltage provided on their corresponding WLs. So, one bitcell can be programmed (or read) at a time. Once programmed, the memory element 402 effectively acts as a resistor. During a read operation, a read voltage (e.g., something lower than programming voltage, such as 1.5 V) can be applied via the WL and BL corresponding to that bitcell, and the resistance of the memory element 402 operates in conjunction with a resistance of a readout circuit so as to provide an indication of its programmed value (either a ‘1’ or a ‘0’, as the case may be).

FIG. 5 illustrates an example embodiment of a chip package 500, in accordance with an embodiment of the present disclosure. As can be seen, chip package 500 includes one or more dies 502. One or more dies 502 may include at least one integrated circuit having a structure as described in any of the aforementioned embodiments. One or more dies 502 may include any other circuitry used to interface with other devices formed on the dies, or other devices connected to chip package 500, in some example configurations.

As can be further seen, chip package 500 includes a housing 504 that is bonded to a package substrate 506. The housing 504 may be any standard or proprietary housing, and may provide, for example, electromagnetic shielding and environmental protection for the components of chip package 500. The one or more dies 502 may be conductively coupled to a package substrate 506 using connections 508, which may be implemented with any number of standard or proprietary connection mechanisms, such as solder bumps, ball grid array (BGA), pins, or wire bonds, to name a few examples. Package substrate 506 may be any standard or proprietary package substrate, but in some cases includes a dielectric material having conductive pathways (e.g., including conductive vias and lines) extending through the dielectric material between the faces of package substrate 506, or between different locations on each face. In some embodiments, package substrate 506 may have a thickness less than 1 millimeter (e.g., between 0.1 millimeters and 0.5 millimeters), although any number of package geometries can be used. Additional conductive contacts 512 may be disposed at an opposite face of package substrate 506 for conductively contacting, for instance, a printed circuit board (PCB). One or more vias 510 extend through a thickness of package substrate 506 to provide conductive pathways between one or more of connections 508 to one or more of contacts 512. Vias 510 are illustrated as single straight columns through package substrate 506 for ease of illustration, although other configurations can be used (e.g., damascene, dual damascene, through-silicon via, or an interconnect structure that meanders through the thickness of substrate 506 to contact one or more intermediate locations therein). In still other embodiments, vias 510 are fabricated by multiple smaller stacked vias, or are staggered at different locations across package substrate 506. In the illustrated embodiment, contacts 512 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 512, to inhibit shorting.

In some embodiments, a mold material 514 may be disposed around the one or more dies 502 included within housing 504 (e.g., between dies 502 and package substrate 506 as an underfill material, as well as between dies 502 and housing 504 as an overfill material). Although the dimensions and qualities of the mold material 514 can vary from one embodiment to the next, in some embodiments, a thickness of mold material 514 is less than 1 millimeter. Example materials that may be used for mold material 514 include epoxy mold materials, as suitable. In some cases, the mold material 514 is thermally conductive, in addition to being electrically insulating.

### Methodology

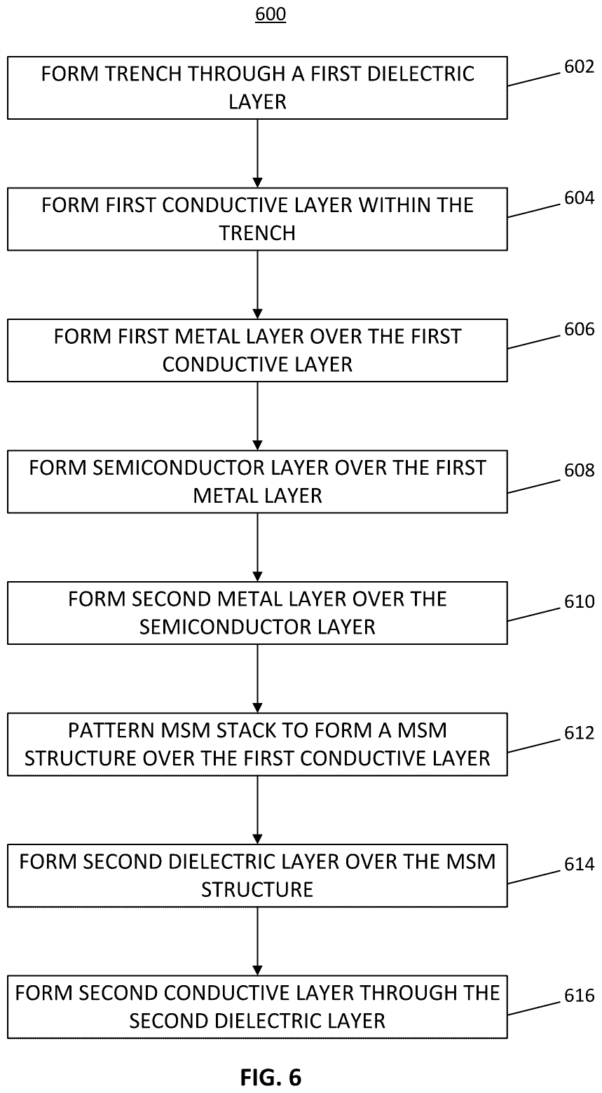

FIG. 6 is a flow chart of a method 600 for forming at least a portion of an integrated circuit, according to an embodiment. Various operations of method 600 may be illustrated in FIGS. 3A-3G. However, the correlation of the various operations of method 600 to the specific components illustrated in the aforementioned figures is not intended to imply any structural and/or use limitations. Rather, the aforementioned figures provide one example embodiment of method 600. Other operations may be performed before, during, or after any of the operations of method 600. Some of the operations of method 600 may be performed in a different order than the illustrated order. In some embodiments, the various operations of method 600 are performed during back end-of-the-line (BEOL) processing, although other applications may benefit from the techniques described herein, including memory and logic cells in frontside or backside interconnect structures, or cells within a device layer.

Method 600 begins with operation 602 where a trench opening is formed through a first dielectric layer, to expose an underlying conductive feature (e.g., via, line, or device contact). The first dielectric layer may be part of an interconnect layer within a plurality of stacked interconnect layers above a plurality of semiconductor devices. The first dielectric layer may be any dielectric material, such as silicon oxide, silicon oxynitride, silicon nitride, or silicon oxycarbide, may be deposited using any known dielectric deposition technique, such as CVD, PECVD, flowable CVD, spin-on dielectric, or ALD. The trench opening may be formed using an anisotropic etching technique, such as RIE.

Method 600 continues with operation 604 where a first conductive layer is formed within the trench opening. The first conductive layer may land on the underlying conductive feature, and include copper, or any other suitable conductive material, that is deposited using any one of electroplating, electroless plating, CVD, or PECVD, to name a few examples. After deposition of the first conductive layer, a polishing process may be performed using, for example, CMP to planarize a top surface of both the first conductive layer and the first dielectric layer. In some embodiments, a thin barrier layer is deposited along the inner surfaces of the trench opening prior to the formation of the first conductive layer.

Method 600 continues with operation 606 where a first metal layer is formed over the first conductive layer. According to some embodiments, the first metal layer is also formed over the first dielectric layer. The first metal layer may include, for example, nickel or titanium and may be deposited using any suitable metal deposition technique. In some examples, the first metal layer has a thickness of around 10 nm, although geometries may vary from one example to the next.

Method 600 continues with operation 608 where a semiconductor layer is formed over the first metal layer. The semiconductor layer may be formed directly on the first metal layer using any suitable deposition technique, such as CVD. The semiconductor layer may include, for example, amorphous silicon, amorphous germanium, or amorphous silicon germanium. The semiconductor layer may be doped, or undoped, and may have a thickness between about 10 nm and about 20 nm. Other semiconductor layer configurations may be used.

Method 600 continues with operation 610 where second metal layer is formed over the semiconductor layer. The second metal layer may be formed directly on the semiconductor layer using any suitable metal deposition technique. The second metal layer may include, for instance, nickel or titanium and may have a thickness of around 10 nm. According to some embodiments, the first metal layer and the second metal layer have substantially the same properties.

Method 600 continues with operation 612 where the MSM stack of the first metal layer, semiconductor layer, and second metal layer are patterned to form an MSM structure over the first conductive layer. The MSM structure may be a part of a via structure formed over the first conductive layer. A masking layer may be used to protect a portion of the MSM stack while the exposed portions of the MSM stack are etched away using any suitable anisotropic etching process. The resulting MSM structure may have a largest plan area (e.g., plan area across the first metal layer) between about 0.45 μm² and about 1 μm². In some embodiments, a dielectric liner is formed over the MSM structure. In some examples, the dielectric liner includes silicon nitride and has a thickness between about 5 nm and about 10 nm.

Method 600 continues with operation 614 where a second dielectric layer is formed over the MSM structure. The second dielectric layer may be any dielectric material, such as silicon oxide, silicon oxynitride, silicon nitride, or silicon oxycarbide and may be deposited using any known dielectric deposition technique. According to some embodiments, the second dielectric layer and the first dielectric layer may have substantially the same properties. The second dielectric layer may represent the dielectric layer of a second interconnect layer above the first interconnect layer.

Method 600 continues with operation 616 where an opening is formed through a portion of the second dielectric layer and a second conductive layer is formed within the opening to contact the MSM structure. The opening may be formed using any anisotropic etching technique, such as using RIE while masking the unetched regions of the second dielectric layer with either a photoresist or hard mask. The RIE etching process may etch through both the second dielectric layer and through the dielectric liner to expose a too portion of the MSM structure (e.g., the second metal layer).

The second conductive layer may include, for example, copper that is deposited using any one of electroplating, electroless plating, CVD, or PECVD, to name a few examples. Any other suitable conductive materials may be used as well. After deposition of the second conductive layer, a polishing process may be performed using, for example, CMP to planarize a top surface of both the second conductive layer and the second dielectric layer. According to some embodiments, the stack of at least the second conductive layer, the second metal layer, the semiconductor layer, and the first metal layer provide a via structure that is conductively coupled with the underlying first conductive layer. According to still other embodiments, the stack of at least the second conductive layer, the second metal layer, the semiconductor layer, and the first metal layer provide a diode structure that provides an access device of a logic or memory cell. In some such cases, the diode structure is used in conjunction with an anti-fuse device, such as the anti-fuse circuit described and shown with reference to FIG. 4.

### Example System

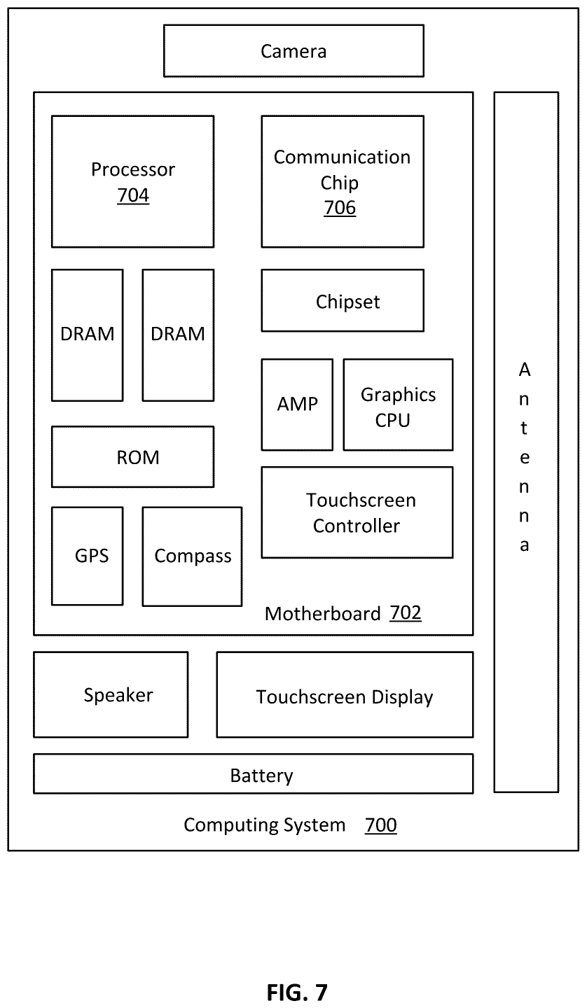

FIG. 7 is an example computing system implemented with one or more of the integrated circuit structures as disclosed herein, in accordance with some embodiments of the present disclosure. As can be seen, the computing system 700 houses a motherboard 702. The motherboard 702 may include a number of components, including, but not limited to, a processor 704 and at least one communication chip 706, each of which can be physically and electrically coupled to the motherboard 702, or otherwise integrated therein. As will be appreciated, the motherboard 702 may be, for example, any printed circuit board (PCB), whether a main board, a daughterboard mounted on a main board, or the only board of system 700, etc.

Depending on its applications, computing system 700 may include one or more other components that may or may not be physically and electrically coupled to the motherboard 702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 700 may include one or more integrated circuit structures or devices configured in accordance with an example embodiment (e.g., a module including an integrated circuit having interconnect structures that have one or more MSM structures integrated in the interconnect region). In some embodiments, multiple functions can be integrated into one or more chips (e.g., for instance, note that the communication chip 706 can be part of or otherwise integrated into the processor 704).

The communication chip 706 enables wireless communications for the transfer of data to and from the computing system 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing system 700 includes an integrated circuit die packaged within the processor 704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 706 also may include an integrated circuit die packaged within the communication chip 706. In accordance with some such example embodiments, the integrated circuit die of the communication chip includes one or more semiconductor devices as variously described herein. As will be appreciated in light of this disclosure, note that multi-standard wireless capability may be integrated directly into the processor 704 (e.g., where functionality of any chips 706 is integrated into processor 704, rather than having separate communication chips). Further note that processor 704 may be a chip set having such wireless capability. In short, any number of processor 704 and/or communication chips 706 can be used. Likewise, any one chip or chip set can have multiple functions integrated therein.

In various implementations, the computing system 700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 700 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a plurality of semiconductor devices, an interconnect region above the plurality of semiconductor devices having a plurality of stacked interconnect layers, a first interconnect layer of the plurality of stacked interconnect layers having a first dielectric layer and a conductive layer, and a second interconnect layer of the plurality of stacked interconnect layers and on the first interconnect layer. The second interconnect layer includes a second dielectric layer over the first dielectric layer, a first metal layer over the conductive layer, a semiconductor layer on the first metal layer, and a second metal layer on the semiconductor layer.

Example 2 includes the integrated circuit of Example 1, wherein the semiconductor layer comprises amorphous silicon.

Example 3 includes the integrated circuit of Example 1 or 2, wherein the semiconductor layer comprises amorphous germanium.

Example 4 includes the integrated circuit of any one of Examples 1-3, wherein the semiconductor layer comprises a p-type or n-type dopant.

Example 5 includes the integrated circuit of any one of Examples 1-4, wherein the semiconductor layer has a thickness between about 10 nm and about 20 nm.

Example 6 includes the integrated circuit of any one of Examples 1-5, wherein the first metal layer and the second metal layer each comprise titanium.

Example 7 includes the integrated circuit of any one of Examples 1-5, wherein the first metal layer and the second metal layer each comprise nickel.

Example 8 includes the integrated circuit of any one of Examples 1-7, wherein the conductive layer comprises copper or tungsten.

Example 9 includes the integrated circuit of any one of Examples 1-8, wherein the conductive layer is a first conductive layer and the second interconnect layer further comprises a second conductive layer on the second metal layer.

Example 10 includes the integrated circuit of Example 9, wherein the second conductive layer, second metal layer, semiconductor layer, and first metal layer form a via structure through the second dielectric layer.

Example 11 includes the integrated circuit of Example 9 or 10, wherein the integrated circuit further comprises a third interconnect layer of the plurality of stacked interconnect layers, the third interconnect layer comprising a third dielectric layer over the second dielectric layer and a third conductive layer on the second conductive layer.

Example 12 includes the integrated circuit of any one of Examples 1-11, wherein the second metal layer, semiconductor layer, and first metal layer form a diode device of a memory or logic cell.

Example 13 includes the integrated circuit of Example 12, wherein the memory or logic cell further includes an anti-fuse device electrically coupled in series with the diode device.

Example 14 is a processor that includes the integrated circuit of any one of Examples 1-13.

Example 15 is a printed circuit board that includes the integrated circuit of any one of Examples 1-13.

Example 16 is an integrated circuit that includes a device layer having a plurality of transistors, an interconnect region above the device layer with the interconnect region having a plurality of stacked interconnect layers. An interconnect layer of the plurality of stacked interconnect layers includes a dielectric layer and a via passing through the dielectric layer. The via includes a first metal layer, a semiconductor layer on the first metal layer, a second metal layer on the semiconductor layer, and a conductive layer on the second metal layer.

Example 17 includes the integrated circuit of Example 16, wherein the semiconductor layer comprises amorphous silicon or amorphous germanium or both.

Example 18 includes the integrated circuit of Example 16 or 17, wherein the semiconductor layer has a thickness between about 10 nm and about 20 nm.

Example 19 includes the integrated circuit of any one of Examples 16-18, wherein the first metal layer and the second metal layer each comprise titanium.

Example 20 includes the integrated circuit of any one of Examples 16-18, wherein the first metal layer and the second metal layer each comprise nickel.

Example 21 includes the integrated circuit of any one of Examples 16-20, wherein the conductive layer comprises copper or tungsten.

Example 22 includes the integrated circuit of any one of Examples 16-21, wherein the conductive layer is a first conductive layer and the first metal layer is disposed over a second conductive layer.

Example 23 includes the integrated circuit of Example 22, wherein the interconnect layer is a first interconnect layer and the dielectric layer is a first dielectric layer, and the integrated circuit further comprises a second interconnect layer beneath the first interconnect layer, wherein the second interconnect layer includes the second conductive layer and a second dielectric layer.

Example 24 includes the integrated circuit of Example 23, wherein the integrated circuit further comprises a third interconnect layer comprising a third dielectric layer above the second dielectric layer and a third conductive layer on the first conductive layer.

Example 25 includes the integrated circuit of any one of Examples 16-24, wherein the second metal layer, semiconductor layer, and first metal layer form a diode device of a memory or logic cell.

Example 26 includes the integrated circuit of Example 25, wherein the memory or logic cell further includes an anti-fuse device electrically coupled in series with the diode device.

Example 27 is a processor that includes the integrated circuit of any one of Examples 16-26.

Example 28 is a printed circuit board that includes the integrated circuit of any one of Examples 16-26.

Example 29 is an electronic device that includes a chip package having one or more dies. At least one of the one or more dies includes a plurality of semiconductor devices, an interconnect region having a plurality of stacked interconnect layers above the plurality of semiconductor devices, a first interconnect layer of the plurality of stacked interconnect layers, and a second interconnect layer of the plurality of stacked interconnect layers. The first interconnect layer includes a first dielectric layer and a conductive layer. The second interconnect layer includes a second dielectric layer above the first dielectric layer, a first metal layer over the conductive layer, a semiconductor layer on the first metal layer, and a second metal layer on the semiconductor layer.

Example 30 includes the electronic device of Example 29, wherein the semiconductor layer comprises amorphous silicon.

Example 31 includes the electronic device of Example 29 or 30, wherein the semiconductor layer has a thickness between about 10 nm and about 20 nm.

Example 32 includes the electronic device of any one of Examples 29-31, wherein the first metal layer and the second metal layer each comprise titanium.

Example 33 includes the electronic device of any one of Examples 29-31, wherein the first metal layer and the second metal layer each comprise nickel.

Example 34 includes the electronic device of any one of Examples 29-33, wherein the conductive layer comprises copper or tungsten.

Example 35 includes the electronic device of any one of Examples 29-34, wherein the conductive layer is a first conductive layer and the second interconnect layer further comprises a second conductive layer on the second metal layer.

Example 36 includes the electronic device of Example 35, wherein the second conductive layer, second metal layer, semiconductor layer, and first metal layer form a via structure through the second dielectric layer.

Example 37 includes the electronic device of Example 36, wherein the at least one of the one or more dies further comprises a third interconnect layer of the plurality of stacked interconnect layers, the third interconnect layer comprising a third dielectric layer above the second dielectric layer and a third conductive layer on the second conductive layer.

Example 38 includes the electronic device of any one of Examples 29-37, further comprising a printed circuit board, wherein the chip package is attached to the printed circuit board.

Example 39 is a method of forming an integrated circuit. The method includes forming a first interconnect layer above a plurality of semiconductor devices and forming a second interconnect layer over the first interconnect layer. Forming the first interconnect layer includes forming a first dielectric layer, forming a trench through the first dielectric layer, and forming a first conductive layer in the trench. Forming the second interconnect layer includes forming a first metal layer over the conductive layer, forming a semiconductor layer on the first metal layer, forming a second metal layer on the semiconductor layer, patterning each of the first metal layer, semiconductor layer, and second metal layer to form a metal-semiconductor-metal (MSM) structure over the conductive layer, forming a second dielectric layer over the first dielectric layer and over the MSM structure, forming a via opening in the second dielectric layer over the MSM structure, and forming a second conductive layer in the via opening and contacting the second metal layer of the MSM structure.

Example 40 includes the method of Example 39, wherein the conductive layer comprises copper or tungsten.

Example 41 includes the method of Example 39 or 40, wherein the semiconductor layer comprises amorphous silicon.

Example 42 includes the method of any one of Examples 39-41, wherein the first metal layer and the second metal layer each comprise titanium or nickel.

Example 43 includes the method of any one of Examples 39-42, further comprising forming a third interconnect layer over the second interconnect layer. Forming the third interconnect layer includes forming a third dielectric layer over the second dielectric layer and forming a third conductive layer on the second conductive layer.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit, comprising:
a plurality of semiconductor devices;
an interconnect region above the plurality of semiconductor devices, the interconnect region comprising a plurality of stacked interconnect layers;
a first interconnect layer of the plurality of stacked interconnect layers, the first interconnect layer comprising a first dielectric layer and a conductive layer; and
a second interconnect layer of the plurality of stacked interconnect layers, the second interconnect layer over the first interconnect layer and comprising
a second dielectric layer over the first dielectric layer,
a first metal layer over the conductive layer,
a semiconductor layer on the first metal layer, and
a second metal layer on the semiconductor layer.

2. The integrated circuit of claim 1, wherein the semiconductor layer comprises amorphous silicon or amorphous germanium.

3. The integrated circuit of claim 1, wherein the semiconductor layer has a thickness between about 10 nm and about 20 nm.

4. The integrated circuit of claim 1, wherein the first metal layer and the second metal layer each comprise titanium or nickel.

5. The integrated circuit of claim 1, wherein the conductive layer is a first conductive layer and the second interconnect layer further comprises a second conductive layer on the second metal layer.

6. The integrated circuit of claim 5, wherein the second conductive layer, second metal layer, semiconductor layer, and first metal layer form a via structure through the second dielectric layer.

7. The integrated circuit of claim 1, wherein the second metal layer, semiconductor layer, and first metal layer form a diode device of a memory or logic cell.

8. The integrated circuit of claim 7, wherein the memory or logic cell further includes an anti-fuse device electrically coupled in series with the diode device.

9. A printed circuit board comprising the integrated circuit of claim 1.

10. An integrated circuit, comprising:
a device layer including a plurality of transistors;
an interconnect region above the device layer, the interconnect region comprising a plurality of stacked interconnect layers;
wherein an interconnect layer of the plurality of stacked interconnect layers comprises a dielectric layer and a via passing through the dielectric layer,
wherein the via comprises a first metal layer, a semiconductor layer on the first metal layer, a second metal layer on the semiconductor layer, and a conductive layer on the second metal layer.

11. The integrated circuit of claim 10, wherein the semiconductor layer comprises amorphous silicon or amorphous germanium or both.

12. The integrated circuit of claim 10, wherein the first metal layer and the second metal layer each comprise titanium or nickel.

13. The integrated circuit of claim 10, wherein the conductive layer is a first conductive layer and the first metal layer is disposed over a second conductive layer.

14. The integrated circuit of claim 13, wherein the interconnect layer is a first interconnect layer and the dielectric layer is a first dielectric layer, and the integrated circuit further comprises a second interconnect layer beneath the first interconnect layer, wherein the second interconnect layer includes the second conductive layer and a second dielectric layer.

15. The integrated circuit of claim 10, wherein the second metal layer, semiconductor layer, and first metal layer form a diode device of a memory or logic cell.

16. An electronic device, comprising:
a chip package comprising one or more dies, at least one of the one or more dies comprising
a plurality of semiconductor devices;
an interconnect region above the plurality of semiconductor devices, the interconnect region comprising a plurality of stacked interconnect layers;
a first interconnect layer of the plurality of stacked interconnect layers, the first interconnect layer comprising a first dielectric layer and a conductive layer; and
a second interconnect layer of the plurality of stacked interconnect layers, the second interconnect layer comprising
a second dielectric layer above the first dielectric layer,
a first metal layer over the conductive layer,
a semiconductor layer on the first metal layer, and
a second metal layer on the semiconductor layer.

17. The electronic device of claim 16, wherein the first metal layer and the second metal layer each comprise titanium or nickel.

18. The electronic device of claim 16, wherein the conductive layer is a first conductive layer and the second interconnect layer further comprises a second conductive layer on the second metal layer.

19. The electronic device of claim 18, wherein the second conductive layer, second metal layer, semiconductor layer, and first metal layer form a via structure through the second dielectric layer.

20. The electronic device of claim 16, further comprising a printed circuit board, wherein the chip package is attached to the printed circuit board.
